(19) United States
(12) Patent Application Publication
(10) Pub. No.: US 2014/0254832 A1
(43) Pub. Date: Sep. 11, 2014

(54) VOLUME ADJUSTING SYSTEM AND METHOD

(71) Applicants: HON HAI PRECISION INDUSTRY CO., LTD., New Taipei (TW); FU TAI HUA INDUSTRY (SHENZHEN) CO., LTD., Shenzhen (CN)

(72) Inventors: XIAN QIAN, Shenzhen (CN); JING-TING WANG, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 13/965,222

(22) Filed: Aug. 13, 2013

(30) Foreign Application Priority Data
Mar. 11, 2013 (CN) 201310075939X

(51) Int. Cl. H03G 5/16

(52) U.S. Cl. CPC H03G 5/16
USPC 381/107

(57) ABSTRACT

A volume adjusting system, a volume adjusting method adapted for a mobile phone, and a computer-readable storage medium encoded with a computer program are disclosed. The mobile phone comprises a speaker and stores an optimal hearing volume and a volume range. The method includes steps: detecting a volume of a telephone voice of a caller when the mobile phone establishes a call communication link with the caller, determining whether or not the volume is within the volume range for optimal hearing, adjusting the volume to the optimal hearing volume when the volume is not within the volume range, and controlling the speaker to output the optimal hearing volume. Therefore, when the mobile phone makes a call, even though the volume of the caller is low or high, the system adjusts the volume to the optimal hearing volume, and it is comfortable for the user of the mobile phone.

### BACKGROUND

1. Technical Field

The disclosure relates to wireless communication technology and, more particularly, to a volume adjusting system and a volume adjusting method adapted for a mobile phone.

2. Description of Related Art

With trends towards miniaturization of mobile phones becoming popular, people often receive an incoming call and call out via the mobile phones. However, when a call volume of a caller is low, people can not hear the caller; and when the call volume of the caller is high, it may be noisy for the people.

Therefore, what is needed is a volume adjusting system to overcome the described shortcoming.

### BRIEF DESCRIPTION OF THE DRAWINGS

FIG. 1 is a block diagram of a mobile phone including a volume adjusting system in accordance with an exemplary embodiment.

FIG. 2 is a block diagram of the volume adjusting system of the mobile phone of FIG. 1.

FIG. 3 is a flowchart illustrating a method of adjusting a volume adapted for the mobile phone of FIG. 1.

### DETAILED DESCRIPTION

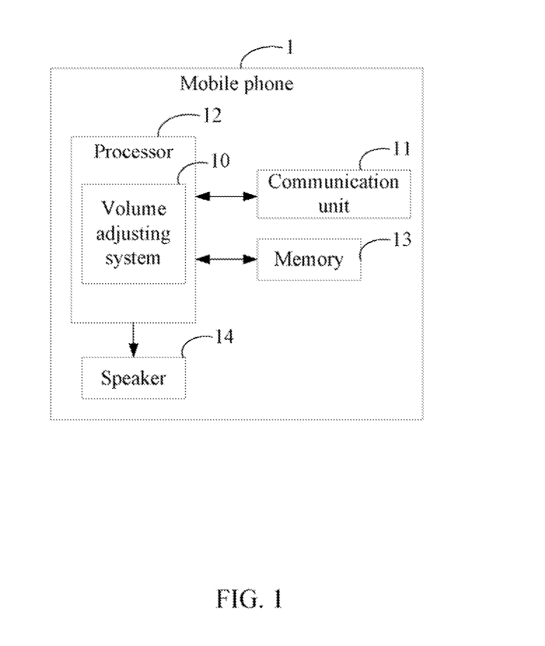

FIG. 1 is a block diagram of a mobile phone including a volume adjusting system in accordance with an exemplary embodiment. The mobile phone 1 includes a communication unit 11, a processor 12, a storage unit 13, and a speaker 14. The mobile phone 1 may establish a communication link via the communication unit 11. The communication unit 11 receives wireless signals from a wireless communication system (not shown) and sends wireless signals to the wireless communication system.

The processor 12 controls the mobile phone 1 to work and perform the volume adjusting system 10. The memory 13 stores data, such as an optimal hearing volume and a volume range for optimal hearing. For example, the optimal hearing volume is fifty five db and the volume range is between fifty db and sixty db. Both the optimal hearing volume and the volume range are predefined by the user of the mobile phone 1. When a call volume of a caller is equal to the optimal hearing volume or within the volume range, a user of the mobile phone 1 hears comfortably. The speaker 14 outputs sound.

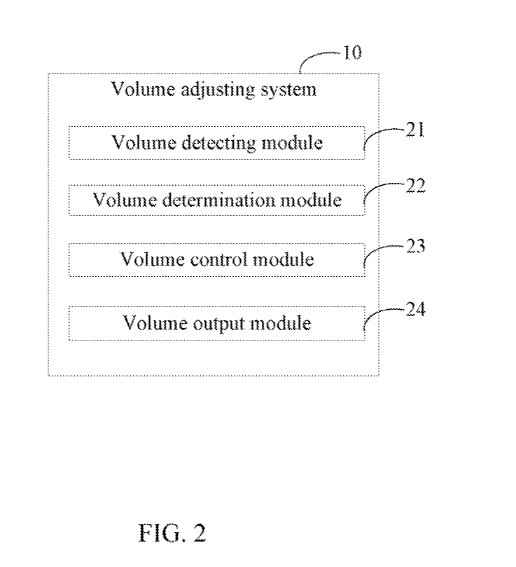

As shown in FIG. 2, the volume adjusting system 10 further includes a volume detecting module 21, a volume determination module 22, a volume control module 23, and a volume output module 24, all of which are collection of software instructions and executed by the processor 12.

When the mobile phone 1 establishes a call communication link with a caller, such as receiving an incoming call from a calling party or outgoing a call to a called party, the volume detecting module 21 detects a volume of a telephone voice of the caller. The volume determination module 22 determines whether or not the volume is within the volume range for optimal hearing. When the volume determination module 22 determines that the volume is within the volume range, it means that the volume is comfortable for the user of the mobile phone 1, the volume output module 24 controls the speaker 14 to output the telephone voice.

When the volume determination module 22 determines that the volume is not within the volume range, it means that the volume is very low or high for the user of the mobile phone 1, the volume control module 23 adjusts the volume to the optimal hearing volume, such as increasing or decreasing the volume to fifty db, the volume output module 24 controls the speaker 14 to output the optimal hearing volume. Therefore, when the mobile phone 1 makes a call, even though the volume of the caller is low or high, the volume adjusting system 10 adjusts the volume to the optimal hearing volume, and it is comfortable for the user of the mobile phone 1.

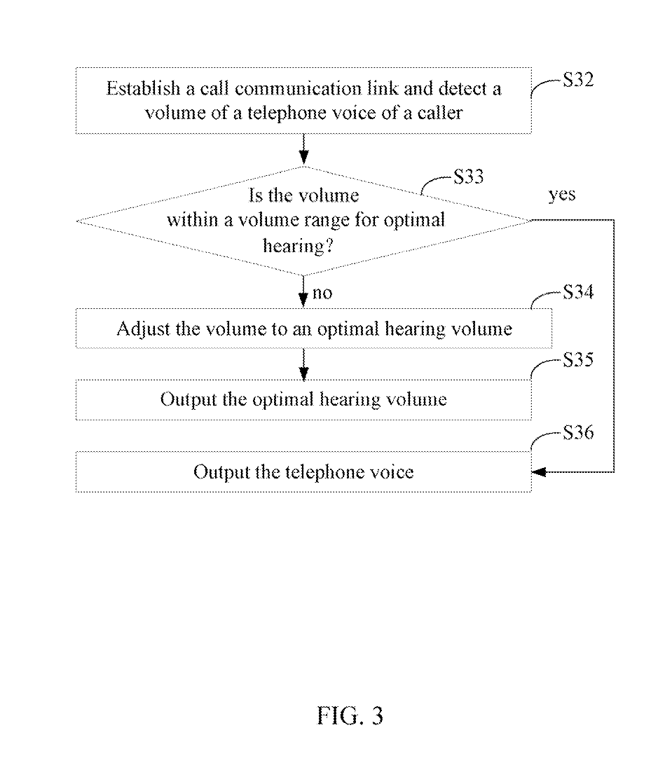

FIG. 3 is a flowchart illustrating a method of adjusting a volume adapted for the mobile phone of FIG. 1. In step S32, when the mobile phone 1 establishes a call communication link with a caller, the volume detecting module 21 detects a volume of a telephone voice of the caller. In step S33, the volume determination module 22 determines whether or not the volume is within the volume range for optimal hearing.

In step S36, when the volume determination module 22 determines that the volume is within the volume range, the volume output module 24 controls the speaker 14 to output the telephone voice.

In step S34, when the volume determination module 22 determines that the volume is not within the volume range, the volume control module 23 adjusts the volume to the optimal hearing volume. In step S35, the volume output module 24 controls the speaker 14 to output the optimal hearing volume.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A volume adjusting system for a mobile phone, wherein the mobile phone comprises a speaker and stores an optimal hearing volume and a volume range for optimal hearing, the volume adjusting system comprising:
one or more processors; and
a plurality of modules to be executed by the one or more processors, the modules comprising:
a volume detecting module to detect a volume of a telephone voice of a caller when the mobile phone establishes a call communication link with the caller;
a volume determination module to determine whether or not the volume is within the volume range for optimal hearing;
a volume control module to adjust the volume to the optimal hearing volume when the volume is not within the volume range; and
a volume output module to controls the speaker to output the optimal hearing volume.

2. The volume adjusting system of claim 1, wherein when the volume is within the volume range, the volume output module is further configured to control the speaker to output the telephone voice.

3. A volume adjusting method adapted for a mobile phone, wherein the mobile phone comprises a speaker and stores an optimal hearing volume and a volume range for optimal hearing, the method comprising:
detecting a volume of a telephone voice of a caller when the mobile phone establishes a call communication link with the caller;
determining whether or not the volume is within the volume range for optimal hearing;
adjusting the volume to the optimal hearing volume when the volume is not within the volume range; and
controlling the speaker to output the optimal hearing volume.

4. The volume adjusting method of claim 3, further comprising:
controlling the speaker to output the telephone voice when the volume is within the volume range.

5. A computer-readable storage medium encoded with a computer program, the program comprising instructions that when executed by one or more computers cause the one or more computers to perform operations for adjusting a volume of a mobile phone, the operations comprising:
detecting a volume of a telephone voice of a caller when the mobile phone establishes a call communication link with the caller;
determining whether or not the volume is within a volume range for optimal hearing;
adjusting the volume to an optimal hearing volume when the volume is not within the volume range; and
outputting the optimal hearing volume.

6. The computer-readable storage medium encoded with a computer program of claim 5, the operations further comprising:
outputting the telephone voice when the volume is within the volume range.
